(19) United States
(12) Patent Application Publication
(10) Pub. No.: US 2023/0044959 A1
(43) Pub. Date: Feb. 9, 2023

(54) SEAT BELT WIRELESS COMMUNICATION SYSTEM AND METHOD

(71) Applicants: Hyundai Motor Company, Seoul (KR); Kia Corporation, Seoul (KR)

(72) Inventors: Young Rok Kim, Suwon (KR); Chang Kyu Bok, Seoul (KR); Beom Jung Kim, Hwaseong (KR)

(21) Appl. No.: 17/729,712

(22) Filed: Apr. 26, 2022

(30) Foreign Application Priority Data
Aug. 9, 2021 (KR) 10-2021-0104837

(51) Int. Cl. B60R 22/48

(52) U.S. Cl. CPC B60R 22/48; B60R 2022/4816; B60R 2022/4866

(57) ABSTRACT

Disclosed are a seat belt wireless communication system and method. The seat belt wireless communication system includes sensing units provided in respective seats and configured to sense whether or not to fasten seat belts, sub-ECUs provided in the respective seats and configured to transmit signals indicating whether or not to fasten the seat belts, sensed by the sensing units, through wireless communication, and a main ECU provided in a vehicle and configured to perform wireless communication with the respective sub-ECUs, to wake up the sub-ECUs through wireless communication, to determine whether or not to fasten the seat belts of the respective seats by receiving the signals from the sub-ECUs after wake-up of the sub-ECUs, and to determine, when the main ECU does not receive a corresponding one of the signals from at least one of the sub-ECUs B, that the corresponding sub-ECU has failed.

### CROSS-REFERENCE TO RELATED APPLICATION

This application claims priority from Korean Patent Application No. 10-2021-0104837, filed on Aug. 9, 2021, in the Korean Intellectual Property Office, the disclosure of which is incorporated herein by reference in its entirety.

### TECHNICAL FIELD

The present invention relates to a seat belt wireless communication system and method. In the seat belt wireless communication system and method, signals indicating whether or not to fasten seat belts in a seat belt reminder system are transmitted by a wireless communication scheme so as to implement various seat functions and to reduce power consumption of batteries.

### BACKGROUND

A seat belt reminder (SBR) system generates a warning light or a warning alarm to induce a passenger sitting on a seat to fasten a seat belt when the passenger does not wear the seat belt during driving of a vehicle at a designated speed or higher.

In such an SBR system, buckles of seat belts and an integrated central control unit (ICU) are electrically connected through wiring, and thus, when the seat belt is locked with the buckle, a buckle locking signal is transmitted to the ICU, and the ICU is connected to a vehicle controller through communication and informs a user that the corresponding seat belt is fastened.

Conventionally, the conventional SBR system is configured such that the signals indicating whether or not to fasten the seat belts are transmitted by a wired communication scheme.

The conventional SBR system is operated by wire and thus a problem in handling of the wiring may be caused, and a reception rate is reduced due to occurrence of an obstacle or the positions of the seats and thus it may be difficult to determine whether or not to fasten the seat belts of the respective seats by receiving the signals indicating whether or not to fasten the corresponding seat belts.

Further, in the conventional SBR system because a main electronic control unit (ECU) and sub EUCs of the vehicle are connected at all times, and thus, the sub ECUs are always on and thus power consumption of the batteries of the sub ECUs is increased.

The above information disclosed in the Background section is only for enhancement of understanding of the background of the invention and should not be interpreted as conventional technology that is already known to those skilled in the art.

### SUMMARY OF THE INVENTION

In preferred aspect, provided are a seat belt wireless communication system and method in which signals indicating whether or not to fasten seat belts in a seat belt reminder system are transmitted by a wireless communication scheme. In particular, data is transmitted by infrared signals, and specific structures are combined so as to implement various seat functions, such as a solution to reduction in a reception rate due to occurrence of an obstacle and the positions of seats.

In an aspect of the present invention, provided is a seat belt wireless communication system including sensing units provided in respective seats and configured to sense whether or not to fasten seat belts, sub-ECUs provided in the respective seats and configured to transmit signals indicating whether or not to fasten the seat belts, sensed by the sensing units, through wireless communication, and a main ECU provided in a vehicle and configured to perform wireless communication with the respective sub-ECUs, to wake up the sub-ECUs through wireless communication, to determine whether or not to fasten the seat belts of the respective seats by receiving the signals from the sub-ECUs after wake-up of the sub-ECUs, and to determine, when the main ECU does not receive a corresponding one of the signals from at least one of the sub-ECUs, that the corresponding sub-ECU has failed.

The sub-ECUs may transmit the signals indicating whether or not to fasten the seat belts, sensed by the sensing units, between the sub-ECUs through wireless communication.

The sub-ECUs may transmit the signals indicating whether or not to fasten the seat belts through wireless communication using an infrared communication scheme, and the signals indicating whether or not to fasten the seat belts are infrared signals.

The sub-ECUs and the main ECU may be disposed on a floor of the vehicle provided with flow path channels of a closed darkroom.

The sub-ECUs may be disposed outside the flow path channels of the darkroom, and slide along the flow path channels of the darkroom.

The seat belt wireless communication system may further include measurement units configured to measure temperatures of batteries of the sub-ECUs when the main ECU determines whether or not to fasten the seat belts of the respective seats by receiving the signals indicating whether or not to fasten the seat belts from the sub-ECUs.

The measurement units may measure the temperatures of the batteries of the sub-ECUs through transistors provided in the measurement units.

In another aspect of the present invention, provided is a seat belt wireless communication method including sensing whether or not to fasten seat belts, transmitting signals indicating whether or not to fasten the seat belts through wireless communication, and performing, by a main ECU, wireless communication with sub-ECUs, waking up the sub-ECUs through wireless communication, determining whether or not to fasten the seat belts of respective seats by receiving the signals from the sub-ECUs after wake-up of the sub-ECUs, and determining, when the main ECU does not receive a corresponding one of the signals from at least one of the sub-ECUs, that the corresponding sub-ECU has failed.

In the transmitting the signals indicating whether or not to fasten the seat belts through wireless communication, the signals indicating whether or not to fasten the seat belts may be transmitted between the sub-ECUs through wireless communication.

The seat belt wireless communication method may further include measuring temperatures of batteries of the sub-ECUs, after the determining whether or not to fasten the seat belts by receiving the signals indicating whether or not to fasten the seat belts from the sub-ECUs.

In the measuring the temperatures of the batteries, when the measured temperatures of the batteries of the sub-ECUs satisfy a reference value, voltages of the batteries of the sub-ECUs may be measured and, when at least one of the measured temperatures of the batteries of the sub-ECUs does not satisfy the reference value, measurement of the voltages of the batteries of the sub-ECUs may be deferred.

In the measuring the temperatures of the batteries, when the measured temperatures of the batteries of the sub-ECUs satisfy a reference value, voltages of the batteries of the sub-ECUs may be measured, and then, when at least one of the measured voltages of the batteries corresponds to a low voltage, the main ECU may give a warning to replace the corresponding battery and, when the measured voltages of the batteries do not correspond to the low voltage, the main ECU may turn off the sub-ECUs.

In another aspect of the present invention, provided is a seat belt wireless communication method including sensing changes in fastened or unfastened states of seat belts, turning on sub-ECUs so as to transmit state change signals of the seat belts when the changes in the fastened or unfastened states of the seat belts are sensed, and receiving, by a main ECU, the state change signals of the seat belts.

The seat belt wireless communication method may further include determining whether or not the main ECU responds to the state change signals, after the receiving the state change signals of the seat belts.

The seat belt wireless communication method may further include, in the determining whether or not the main ECU responds to the state change signals, when the main ECU responds to the state change signals, turning off the sub-ECUs, and when the main ECU does not respond to the state change signals, turning on the sub-ECUs so as to transmit the state change signals of the seat belts.

Also provided is a vehicle including the seat belt wireless communication system as described herein.

Other aspects of the invention are disclosed infra.

### BRIEF DESCRIPTION OF THE DRAWINGS

The above and other objects, features and other advantages of the present invention will be more clearly understood from the following detailed description taken in conjunction with the accompanying drawings, in which:

FIG. 1 shows an exemplary seat belt wireless communication system according to an exemplary embodiment of the present invention;

FIG. 2 shows an exemplary seat belt wireless communication system according to an exemplary embodiment of the present invention;

FIG. 3 shows an exemplary method for operating the seat belt wireless communication system shown in FIG. 1; and

FIG. 4 shows an exemplary method for operating a seat belt wireless communication system according to an exemplary embodiment of the present invention.

### DETAILED DESCRIPTION

Specific structural or functional descriptions in embodiments of the present invention set forth in the description which follows will be exemplarily given to describe the embodiments of the present invention. However, the present invention may be embodied in many alternative forms, and should not be construed as being limited to the embodiments set forth herein. Reference will now be made in detail to the preferred embodiments of the present invention, examples of which are illustrated in the accompanying drawings. Unless otherwise indicated, all numbers, values, and/or expressions referring to quantities of ingredients, reaction conditions, polymer compositions, and formulations used herein are to be understood as modified in all instances by the term “about” as such numbers are inherently approximations that are reflective of, among other things, the various uncertainties of measurement encountered in obtaining such values.

Further, unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

In the present specification, when a range is described for a variable, it will be understood that the variable includes all values including the end points described within the stated range. For example, the range of “5 to 10” will be understood to include any subranges, such as 6 to 10, 7 to 10, 6 to 9, 7 to 9, and the like, as well as individual values of 5, 6, 7, 8, 9 and 10, and will also be understood to include any value between valid integers within the stated range, such as 5.5, 6.5, 7.5, 5.5 to 8.5, 6.5 to 9, and the like. Also, for example, the range of “10% to 30%” will be understood to include subranges, such as 10% to 15%, 12% to 18%, 20% to 30%, etc., as well as all integers including values of 10%, 11%, 12%, 13% and the like up to 30%, and will also be understood to include any value between valid integers within the stated range, such as 10.5%, 15.5%, 25.5%, and the like.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

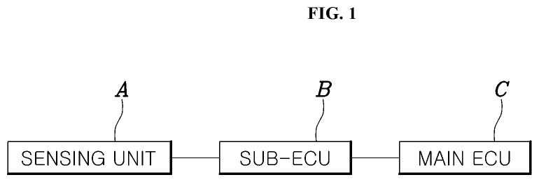

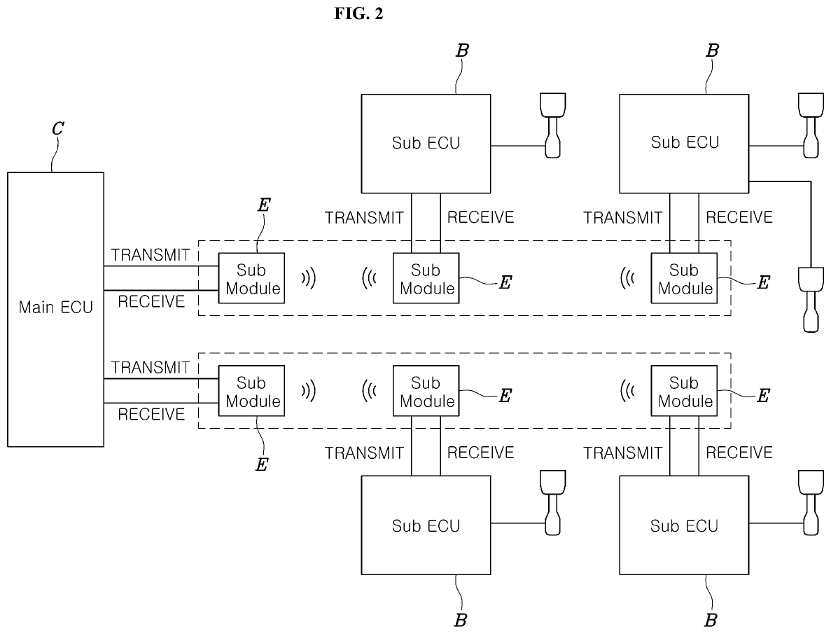

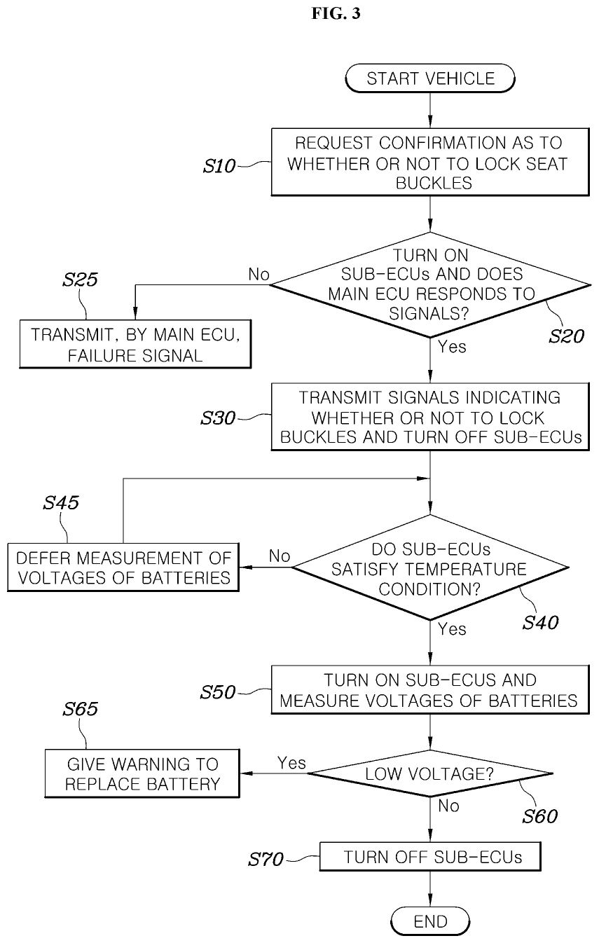

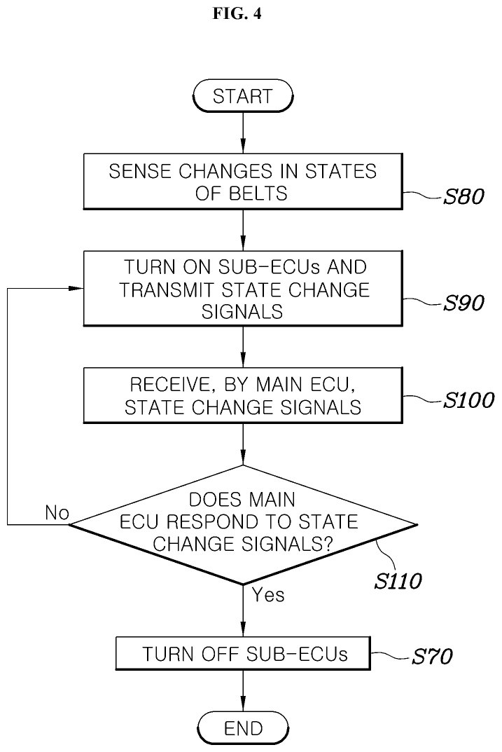

FIG. 1 shows an exemplary seat belt wireless communication system according to an exemplary embodiment of the present invention. FIG. 2 shows another exemplary seat belt wireless communication system according to an exemplary embodiment of the present invention. FIG. 3 shows a flowchart illustrating an exemplary method for operating the seat belt wireless communication system shown in FIG. 1. FIG. 4 shows a flowchart illustrating an exemplary method for operating a seat belt wireless communication system according to another exemplary embodiment of the present invention.

FIG. 1 shows an exemplary seat belt wireless communication system according to one embodiment of the present invention. For instance, the seat belt wireless communication system includes sensing units A provided in respective seats and configured to sense whether or not to fasten seat belts, sub-ECUs B provided in the respective seats and configured to transmit signals indicating whether or not to fasten the seat belts, sensed by the sensing units A, through wireless communication, and a main ECU C provided in a vehicle and configured to perform wireless communication with the respective sub-ECUs B, to wake up the sub-ECUs B through wireless communication, to determine whether or not to fasten the seat belts of the respective seats by receiving the signals from the sub-ECUs B after wake-up of the sub-ECUs B, and to determine, when the main ECU C does not receive a corresponding one of the signals from at least one of the sub-ECUs B, that the corresponding sub-ECU B has failed.

In particular, signals indicating whether or not to fasten seat belts in a seat belt reminder (SBR) system are transmitted by a wireless communication scheme, and specific structures are combined so as to solve reduction in a reception rate due to occurrence of an obstacle and the positions of seats. For this purpose, a situation, in which the signals indicating whether or not to fasten the seat belts are transmitted through wireless communication, whether or not to fasten the seat belts of the respective seats is determined by receiving the signals, and it is determined, when the signal is not received from at least one of the sub-ECUs B after wake-up of the sub-ECU B, that the corresponding sub-ECUs B has failed, must be created.

The seat belt has been known as the most important and effective safety device for among vehicle safety devices. In South Korea, the seat belt wearing rate, particularly, the seat belt wearing rate of passengers sitting on rear seats, during driving of vehicles is low. According to the latest surveys, the seat belt wearing rate of passengers sitting on rear seats is about 20%. The seat belt reminder (SBR) system configured to inform a driver of whether or not to fasten seat belts generates a warning light or a warning alarm to induce a passenger sitting on a seat to fasten the corresponding seat belt when the passenger does not wear the seat belt during driving of the vehicle at a designated speed or higher. In such an SBR system, buckles of the seat belts and an integrated central control unit (ICU) are electrically connected through wiring, and thus, when the seat belt is locked with the corresponding buckle, a buckle locking signal is transmitted to the ICU, and the ICU is connected to a vehicle controller through communication and informs that the corresponding seat belt is fastened. The conventional SBR system is operated by wire and thus a problem in handling of the wiring may be caused, and a reception rate is reduced due to occurrence of an obstacle or the positions of the seats and thus it may be difficult to determine whether or not to fasten the seat belts of the corresponding seats by receiving the signals indicating whether or not to fasten the respective seat belts and it may be difficult to induce a driver to wear the seat belt by generating a warning light or a warning alarm when the driver does not wear the seat belt. Further, because a main electric control unit (ECU) and sub-ECUs of the vehicle are connected at all times, and thus, the sub ECUs are always on and thus power consumption of the batteries of the sub ECUs is increased. While the conventional SBR system is operated by wire, the present invention is characterized in that the signals indicating whether or not to fasten the seat belts are transmitted by a wireless communication scheme so as to implement various seat functions.

However, in an SBR system configured to transmit signals indicating whether or not to fasten seat belts through wireless communication during driving of a vehicle, the reception rate of the signals may be reduced due to interference with an obstacle, or the reception rate of the signals may be reduced due to a long distance between the positions of respective seats disposed in the vehicle. Recently, technologies that transceive data through radio waves, such as Wi-Fi or Bluetooth, are representatively used in wireless communication, and in general, wireless communication schemes other than wired communication schemes may be performed through infrared light, ultra-wideband, etc. In optical wireless communication, although visible light can be used, infrared light rather than visible light is often used as a transmission medium. Infrared communication using infrared light may transmit data at a high speed, because infrared light has longer wavelengths than visible light and may thus smoothly pass through fine particles floating in the air, and may secure a wide bandwidth compared to radio waves when a distance between devices is short. On account of this advantage, most of optical wireless communication-based devices, which are used recently, employ an infrared communication method. The major drawbacks of infrared communication may be that a communication distance is several meters, i.e., is short, and transceivers need to face each other, but these drawbacks may rather increase security because communication is possible only within a short distance and at a predetermined angle.

Therefore, provided is a seat belt wireless communication system such that the sub-ECUs B are woken up through wireless communication by a wireless communication scheme using infrared light, whether or not to fasten the seat belts of the respective seats are determined by receiving the signals indicating whether or not to fasten the seat belts from the sub-ECUs B after wake-up of the sub-ECUs B, and it is determined, when the signal is not received from at least one of the sub-ECUs B after wake-up of the sub-ECUs B, that the corresponding sub-ECU B has failed, so as to implement various seat functions, such as a solution to reduction in a reception rate due to occurrence of an obstacle and the positions of the seats, by preparing flow path channels of a closed darkroom.

Particularly, the sensing units A are provided in the respective seats in the vehicle, and senses whether or not to fasten the corresponding seat belts. The sensing units A are disposed in coupling units of the seat belts, and thereby, a driver may sense whether or not to fasten the seat belts. Further, the sub-ECUs B are provided in the respective seats, and transmit the signals indicating whether or not to fasten the seat belts, sensed by the sensing unit A, through wireless communication. The sub-ECUs B is disposed in the respective seats, and may transmit the signals received from the sensing units A between the sub-ECUs B or to the main ECU C through wireless communication. The sub-ECUs B provided in the respective seats may transmit the signals indicating whether or not to fasten the seat belts to the main ECU C or between the sub-ECUs B via sub-modules E through wireless communication.

Further, the main ECU C is provided in the vehicle, and is configured to perform the wireless communication with the respective sub-ECUs B, to wake up the sub-ECUs B through wireless communication, to determine whether or not to fasten the seat belts of the respective seats by receiving the signals from the sub-ECUs B after wake-up of the sub-ECUs B, and to determine, when the main ECU C does not receive the signal from at least one of the sub-ECUs B, that the corresponding sub-ECU B has failed. When the vehicle is started up, the main ECU C and the sub-ECUs B are turned on in order. The main ECU C provided in the vehicle is first woken up and, when the main ECU C is woken up, whether or not the main ECU C has failed is diagnosed. Thereafter, the main ECU C may perform wireless communication with the sub-ECUs B.

When the main ECU C performs wireless communication with the sub-ECUs B, the main ECU C controls wake-up of the sub-ECUs B through wireless communication, receives the signals indicating whether or not to fasten the seat belts of the respective seats through the respective sub-ECUs B, and determines whether or not to fasten the seat belts of the respective seats. When the main ECU C determines whether or not to fasten the seat belts of the respective seats by receiving the signals indicating whether or not to fasten the seat belts, the main ECU C transmits the signals to the outside. Here, when the main ECU C does not receive the signal from at least one of the sub-ECUs B after wake-up of the sub-ECUs B, the main ECU C determines that the corresponding sub-ECU B is not capable of transmitting the signal indicating whether or not to fasten the corresponding seat belt through wireless communication, and thus determines that the corresponding sub-ECU B has failed. The main ECU C receives the signals indicating whether or not to fasten the seat belts of the respective seats from the sub-ECUs B, the signals are transmitted from the sub-ECUs B to the main ECU C, and then, the main ECU C transmits a seat belt wearing signal to an integrated central control unit.

Further, when the main ECU C determines whether or not to fasten the seat belts of the respective seats by receiving the signals indicating whether or not to fasten the seat belts of the respective seats from the sub-ECUs B, and transmits the seat belt wearing signal, the main

ECU C may turn off the sub-ECUs B so as to reduce power consumption of the sub-ECUs B. Further, when the main ECU C does not receive the signal from at least one of the sub-ECUs B, the main ECU C may determine that the corresponding sub-ECU B is not capable of transmitting the signal indicating whether or not to fasten the corresponding seat belt through wireless communication, may determine that the corresponding sub-ECU B has failed, and may transmit a failure signal. The seat belt wearing signal and the failure signal transmitted by the main ECU C may be repeatedly transmitted. The main ECU C may determine whether or not to fasten the seat belts of the respective seats by receiving the signals indicating whether or not to fasten the seat belts of the respective seats from the sub-ECUs B, and may transmit the seat belt wearing signal, and, when the main ECU C does not receive the signal from at least one of the sub-ECUs B, the main ECU C may determine that the corresponding sub-ECU B has failed, and may transmit the failure signal. Particularly, in order to prepare for a case that the driver is not capable of recognizing the seat belt wearing signal and the failure signal due to signal omission, the main ECU C may repeatedly transmit the seat belt wearing signal and the failure signal.

FIG. 2 shows an exemplary seat belt wireless communication system according to an exemplary embodiment of the present invention.

As shown in FIG. 2, for example, the sub-ECUs B are characterized in that they transmit the signals indicating whether or not to fasten the seat belts of the respective seats, sensed by the sensing units A, between the sub-ECUs B through wireless communication. The sub-ECUs B are prepared in the equal number to the seats disposed in the vehicle. The signals indicating whether or not to fasten the seat belts of the respective seats, transmitted by the sub-ECUs B may be received by the main ECU C, or may be transceived between the sub-ECUs B provided in the respective seats through wireless communication. As consequence, in the system in which the sub-ECUs B and the main ECU C are connected, when one of the sub-ECUs B is diagnosed as a failure, another sub-ECU B may receive the signal indicating whether or not to fasten the seat belt corresponding to the sub-ECU B diagnosed as the failure, and may transmit the signal indicating whether or not to fasten the corresponding seat belt to the main ECU C.

The sub-ECUs B may transmit the signals indicating whether or not to fasten the corresponding seat belts through wireless communication using an infrared communication scheme, and the signals indicating whether or not to fasten the seat belts may be infrared signals.

The infrared communication scheme uses light as a medium, and may transmit data at a high speed, because infrared light has longer wavelengths than visible light and thus secures a wide bandwidth compared to radio waves when a distance between devices is short. Therefore, the infrared communication scheme using infrared signals is appropriate when a distance between devices is short, and a distance between seats of a vehicle is appropriate for the infrared communication scheme and thus data may be transmitted at a high speed.

The sub-ECUs B and the main ECU C may be disposed on the floor of a vehicle provided with flow path channels of a closed darkroom.

The infrared communication scheme using infrared signals has a drawback in that the reception rate of infrared signals is remarkably reduced when there is an obstacle between the seats of the vehicle. In this case, when the main ECU C does not receive the signal from at least one of the sub-ECUs B wake-up of the sub-ECUs B, the main ECU C is not capable of determining whether or not to fasten the seat belts of the respective seats and determining that the corresponding sub-ECU B has failed, and thus, the functions of the seat belt reminder may not be completely performed. Because infrared observation equipment or an infrared sensor may effectively sense infrared light only when its own temperature is low, it is very important to cool the infrared observation equipment or the infrared sensor. Therefore, the reduction in the reception ratio of the signals received from the sub-ECUs B may be solved by preparing the flow path channels of the closed darkroom.

The sub-ECUs B may be disposed outside the flow path channels of the darkroom, and may slide along the flow path channels of the darkroom.

The sub-ECUs B may transmit the signals indicating whether or not to fasten the seat belts through the flow path channels of the closed darkroom. The sub-ECUs B may be disposed outside the flow path channels of the darkroom, the sub-ECUs B at the lower parts of the flow path channels may transceive the signals indicating whether or not to fasten the seat belts, and the sub-ECUs B at the upper parts of the flow path channels may transmit the signals indicating whether or not to fasten the seat belts, received from the sensing units A, between the sub-ECUs B or to the main ECU C.

Further, because the seats of the vehicles are disposed in a straight line so that passengers can easily access the seats, the signals indicating whether or not to fasten the seat belts through the infrared communication scheme using infrared signals may be transmitted by enabling the sub-ECUs B to slide along the flow path channels of the darkroom. The sub-ECUs B provided in the respective seats may transmit the signals indicating whether or not to fasten the corresponding seat belts to the main ECU C through the sub-modules E via wireless communication, or may mutually transmit the signals between the sub-ECUs B via wireless communication. Here, the sub-ECUs B are provided in the respective seats outside the flow path channels of the darkroom and, in this case, the sub-ECUs B are disposed to be spaced apart outwards from the flow path channels of the darkroom by the positions of the respective seats, and are continuously disposed. Wireless communication of the signals indicating whether or not to fasten the seat belts through the infrared communication scheme is appropriate when a distance between devices is short, and a distance between the seats of the vehicle is appropriate for the infrared communication scheme and thus data may be transmitted at a high speed.

The seat belt wireless communication system may further include measurement units configured to measure the temperatures of batteries of the sub-ECUs B when the main ECU C determines whether or not to fasten the seat belts of the respective seats by receiving the signals indicating whether or not to fasten the seat belts from the sub-ECUs B.

In order to prevent occurrence of a low-voltage warning even in the actually operable state of the sub-ECU B, such as an increase or a decrease in the temperature of the battery from an extremely low temperature, at which a person is not capable of sitting, a short time after a passenger gets in the vehicle, check of the voltage of the battery of the corresponding sub-ECU B may be deferred until the temperature of the battery of the sub-ECU B enters a designated temperature condition. When the main ECU C determines whether or not to fasten the seat belts of the seats by receiving the signals indicating whether or not to fasten the seat belts from the sub-ECUs B and transmits the seat belt wearing signal, the measurement units may measure the temperatures of the batteries of the sub-ECUs B. When the battery of at least one of the sub-ECU B is measured as having low voltage, a warning to replace the battery of the corresponding sub-ECU B or the main ECU C may be given, and when it is determined that the capacities of the batteries of the sub-ECUs B are sufficient, the sub-ECUs B may be turned off so as to reduce power consumption.

The measurement units may measure the temperatures of the batteries of the sub-ECUs B through transistors provided in the measurement units.

The transistor is a semiconductor device which adjusts current or voltage flow and thus serves as a switch, and may serve to measure the temperature of the battery in the seat belt wireless communication system according to the present invention. The reference temperature of the transistor provided in the seat belt wireless communication system is set to prevent occurrence of a low-voltage warning even in the actually operable state of the sub-ECU B, such as an increase or a decrease in the temperature of the battery a short time after a passenger gets in the vehicle. The reference temperature set by the transistor is in the range of about −30 to 80 degrees, and check of the voltage of the battery is delayed until the temperature of the battery enters the set temperature condition.

FIG. 3 shows an exemplary method for operating the seat belt wireless communication system shown in FIG. 1.

As shown in FIG. 3, a seat belt wireless communication system includes sensing whether or not to fasten seat belts (S10), transmitting signals indicating whether or not to fasten the seat belts through wireless communication (S20), performing, by a main ECU C, wireless communication with respective sub-ECUs B, waking up the sub-ECUs B through wireless communication, and determining whether or not to fasten the seat belts of respective seats by receiving the signals from the sub-ECUs B after wake-up of the sub-ECUs B (S30), and determining, when the main ECU C does not receive a corresponding one of the signals from at least one of the sub-ECUs B, that the corresponding sub-ECU B has failed (S25).

In transmission of the signals indicating whether or not to fasten the seat belts through wireless communication (S20), the signals indicating whether or not to fasten the seat belts, sensed by the sensing units A, are transmitted between the sub-ECUs B through wireless communication.

The seat belt wireless communication method may further include measuring the temperatures of the batteries of the sub-ECUs B (S40), after determination as to whether or not to fasten the seat belts of the respective seats by receiving the signals from the sub-ECUs B (S30).

In measurement of the temperatures of the batteries (S40), when the measured temperatures of the batteries of the sub-ECUs B satisfy a reference value, the voltages of the batteries of the sub-ECUs B may be measured (S50), and when at least one of the measured temperatures of the batteries of the sub-ECUs B does not satisfy the reference value, measurement of the voltages of the batteries of the sub-ECUs B may be put on standby (S45).

In measurement of the temperatures of the batteries (S40), when the measured temperatures of the batteries of the sub-ECUs B satisfy the reference value, the voltages of the batteries of the sub-ECUs B are measured (S50), and then, when at least one of the measured voltages of the batteries corresponds to a low voltage (Yes in S60), the main ECU C gives a warning to replace the corresponding battery (S65), and when the measured voltages of the batteries do not correspond to the low voltage (No in S60), the sub-ECUs B are turned off (S70).

FIG. 4 shows an exemplary method for operating a seat belt wireless communication system according to an exemplary embodiment of the present invention.

As shown in FIG. 4, a seat belt wireless communication system according to an exemplary embodiment of the present invention includes sensing changes in the fastened or unfastened states of seat belts (S80), turning on sub-ECUs B so as to transmit state change signals of the seat belts when the changes in the fastened or unfastened states of the seat belts are sensed (S90), and receiving, by a main ECU C, the state change signals of the seat belts (S100).

The seat belt wireless communication method according to an exemplary embodiment of the present invention may further include determining whether or not the main ECU C responds to the state change signals (S110), after reception of the state change signals of the seat belts (S100).

The seat belt wireless communication method according to an exemplary embodiment of the present invention may further include, in response to the state change signals (S110), when the main ECU C responds to the state change signals, turning off the sub-ECUs B (S70) and, when the main ECU C does not respond to the state change signals, turning on the sub-ECUs B (S90) so as to transmit the state change signals of the seat belts. In this case, when the main ECU C receives the state change signals of the seat belts and then responds thereto, the main ECU C turns off the sub-ECUs B, thereby reducing power consumption of the sub-ECUs B and thus increasing power efficiency compared to the conventional seat belt reminder system.

According to various exemplary embodiments of the present invention, in a seat belt wireless communication system and method, signals indicating whether or not to fasten seat belts in a seat belt reminder system are transmitted by a wireless communication scheme, and specific structures are combined so as to implement various seat functions, such as a solution to reduction in a reception rate due to occurrence of an obstacle and the positions of seats and reduction in power consumption of batteries.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A seat belt wireless communication system comprising:
sensing units provided in respective seats and configured to sense whether or not to fasten seat belts;
sub-electronic control units (ECUs) provided in the respective seats and configured to transmit signals indicating whether or not to fasten the seat belts, sensed by the sensing units, through wireless communication; and
a main electronic control unit (ECU) provided in a vehicle and configured to perform wireless communication with the respective sub-ECUs, to wake up the sub-ECUs through wireless communication, to determine whether or not to fasten the seat belts of the respective seats by receiving the signals from the sub-ECUs after wake-up of the sub-ECUs, and to determine, when the main ECU does not receive a corresponding one of the signals from at least one of the sub-ECUs, that the corresponding sub-ECU has failed.

2. The seat belt wireless communication system according to claim 1, wherein the sub-ECUs transmit the signals indicating whether or not to fasten the seat belts, sensed by the sensing units, between the sub-ECUs through wireless communication.

3. The seat belt wireless communication system according to claim 1, wherein the sub-ECUs transmit the signals indicating whether or not to fasten the seat belts through wireless communication using an infrared communication scheme, and the signals indicating whether or not to fasten the seat belts are infrared signals.

4. The seat belt wireless communication system according to claim 1, wherein the sub-ECUs and the main ECU are disposed on a floor of the vehicle provided with flow path channels of a closed darkroom.

5. The seat belt wireless communication system according to claim 4, wherein the sub-ECUs are disposed outside the flow path channels of the darkroom, and slide along the flow path channels of the darkroom.

6. The seat belt wireless communication system according to claim 1, further comprising measurement units configured to measure temperatures of batteries of the sub-ECUs when the main ECU determines whether or not to fasten the seat belts of the respective seats by receiving the signals indicating whether or not to fasten the seat belts from the sub-ECUs.

7. The seat belt wireless communication system according to claim 6, wherein the measurement units measure the temperatures of the batteries of the sub-ECUs through transistors provided in the measurement units.

8. A seat belt wireless communication method comprising:
sensing whether or not to fasten seat belts;
transmitting signals indicating whether or not to fasten the seat belts through wireless communication; and
performing, by a main electronic control unit (ECU), wireless communication with sub-electronic control units (ECUs), waking up the sub-ECUs through wireless communication, determining whether or not to fasten the seat belts of respective seats by receiving the signals from the sub-ECUs after wake-up of the sub-ECUs, and determining, when the main ECU does not receive a corresponding one of the signals from at least one of the sub-ECUs, that the corresponding sub-ECU has failed.

9. The seat belt wireless communication method according to claim 8, wherein, in the transmitting the signals indicating whether or not to fasten the seat belts through wireless communication, the signals indicating whether or not to fasten the seat belts are transmitted between the sub-ECUs through wireless communication.

10. The seat belt wireless communication method according to claim 8, further comprising:
measuring temperatures of batteries of the sub-ECUs, after the determining whether or not to fasten the seat belts by receiving the signals indicating whether or not to fasten the seat belts from the sub-ECUs.

11. The seat belt wireless communication method according to claim 10, wherein, in the measuring the temperatures of the batteries, when the measured temperatures of the batteries of the sub-ECUs satisfy a reference value, voltages of the batteries of the sub-ECUs are measured and, when at least one of the measured temperatures of the batteries of the sub-ECUs does not satisfy the reference value, measurement of the voltages of the batteries of the sub-ECUs is deferred.

12. The seat belt wireless communication method according to claim 10, wherein, in the measuring the temperatures of the batteries, when the measured temperatures of the batteries of the sub-ECUs satisfy a reference value, voltages of the batteries of the sub-ECUs are measured, and then, when at least one of the measured voltages of the batteries corresponds to a low voltage, the main ECU gives a warning to replace the corresponding battery and, when the measured voltages of the batteries do not correspond to the low voltage, the main ECU turns off the sub-ECUs.

13. A seat belt wireless communication method comprising:
sensing changes in fastened or unfastened states of seat belts;
turning on sub-electronic control units (ECUs) so as to transmit state change signals of the seat belts when the changes in the fastened or unfastened states of the seat belts are sensed; and
receiving, by a main electronic control units (ECU), the state change signals of the seat belts.

14. The seat belt wireless communication method according to claim 13, further comprising:
determining whether or not the main ECU responds to the state change signals, after the receiving the state change signals of the seat belts.

15. The seat belt wireless communication method according to claim 14, further comprising, in the determining whether or not the main ECU responds to the state change signals, when the main ECU responds to the state change signals, turning off the sub-ECUs and, when the main ECU does not respond to the state change signals, turning on the sub-ECUs so as to transmit the state change signals of the seat belts.
